(19) United States
(12) Patent Application Publication
(10) Pub. No.: US 2006/0225652 A1
(43) Pub. Date: Oct. 12, 2006

(54) Apparatus for vacuum coating of substrates of various sizes

(75) Inventors: Wolfgang Erbkamm, Dresden (DE); Jochen Krause, Dresden (DE); Dietmar Schulze, Dresden (DE); Hans-Christian Hecht, Weinboehla (DE)

Correspondence Address: HESLIN ROTHENBERG FARLEY & MESITI PC, 5 COLUMBIA CIRCLE, ALBANY, NY, 12203, US

(73) Assignee: VON ARDENNE Anlagentechnik GmbH, Sacka (DE)

(21) Appl. No.: 11/400,856

(22) Filed: Apr. 10, 2006

(30) Foreign Application Priority Data
Apr. 8, 2005 (DE) 102005016405.6-45

(51) Int. Cl. C23C 16/00

(52) U.S. Cl. 118/719

(57) ABSTRACT

The invention concerns an apparatus for vacuum coating of substrates of various sizes that consists of lock chambers at the entrance and at the exit and several processing chambers arranged one behind the other as well as of a conveying system for the sequential transport of substrates with a certain substrate width through the lock chambers and for their continuous transport through the coating chambers. The lock and processing chambers each have a chamber width that corresponds to the substrate width, and the lock chamber is characterized by a loading area A_{L} having a width b and a length l that indicates the size of substrate that can be accommodated. The object of the apparatus according to the invention is to better utilize the coatable area of each processing chamber so that less coating material is wasted. The object is solved by making the ratio R of width to length R=w/l greater than a minimum ratio Rₘᵢₙ where R_{min =0.95-0.019 A}_{L}.

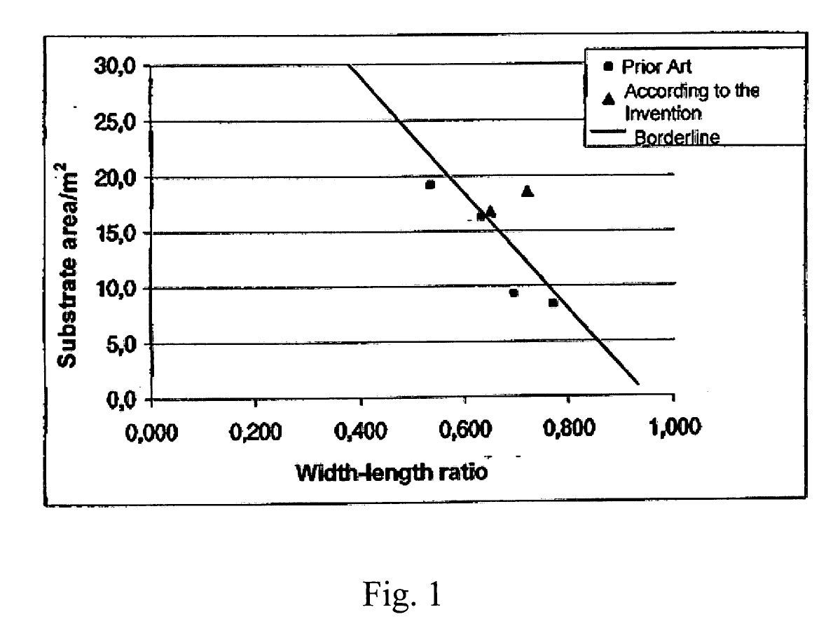

### CROSS-REFERENCE OF RELATED APPLICATION

This application claims priority from German Patent Application No. DE 10 2005 016 405.6-45, filed on Apr. 8, 2005, the entire disclosure of which is incorporated herein by reference.

### BACKGROUND OF THE INVENTION

The present invention relates to an apparatus for vacuum coating of substrates, in particular, flat glass panels, of various sizes.

Known coating plants for vacuum coating of substrates, particularly of flat glass panels, consist of several lock and coating chambers and the like—hereinafter referred to as processing chambers—all arranged one behind the other, as well as of a conveying system to transport the substrates sequentially through the lock chambers and to move them continuously through the coating chambers. The substrates have a certain width to which the width of the processing chambers corresponds, i.e., the processing chambers have the same width as the substrates plus an additional width that is technically necessary, e.g., for the conveying system.

Flat glass panels come in standard dimensions. They are customarily manufactured in the following sizes: 6000 mm×3210 mm, about 100″×126″(2540 mm×3210 mm), or 100″×144″(2540 mm×3658 mm).

Known coating plants therefore have a width that allows for the coating of flat glass panels measuring 100″×126″, with the longer sides of these panels transverse (at right angle) to the direction of movement. The interior of the processing chambers is therefore designed for receiving two panels, each measuring 100″×126″ and placed one behind the other transverse to the transport direction. That is, the processing chambers are at least 126″ wide and 200″ long. Consequently, two such panels can be coated simultaneously in each coating unit, which increases the throughput of such a coating unit compared to what would be the case if the panels were positioned with the longer sides in line with the direction of transport. In particular, two panels can enter the lock chamber at the same time and then be transported continuously through the coating chambers.

The efficiency of such coating plants is, however, very limited. Efficiency here is measured by the coating performance, that is, by the substrate surface area that is coated at a standard speed of 1 m/min. This coating area amounts to 3.21 m/min for coating units designed for the 100″×126″ or the 3210 mm×6000 mm formats.

Panels measuring 100″×144″ can also be processed in such coating units; however, the lock chamber can receive only one such panel at a time that is then to be coated in the processing chamber. Hence, the efficiency of such coating units is further limited when large-format panels are vacuum coated. Furthermore, the coatable area of the processing chambers is used very inefficiently in this procedure, since a panel measuring 100″×144″ uses only about 57% of the area that two 100″×126″ panels take up.

Aside from the fact that in this process a large amount of coating material is wasted because it is not deposited on a substrate, another drawback of the process is that this coating material is instead deposited on components of the coater apparatus where it leads to increased cleaning time and effort. For this reason, substrates of the 100″×144″ format are customarily vacuum coated in coating units whose chamber width is designed to accommodate a substrate width of 100″.

### SUMMARY OF INVENTION

Accordingly, one of the goals of the present invention is to improve upon an apparatus of the type described in such a way that it can be used to coat flat substrates, such as flat glass panels, of various sizes with high efficiency while making efficient use of the coatable area of each processing chamber and reducing waste of coating material.

According to the invention, the problem is solved by an apparatus with the features as defined in Claim 1. Advantageous embodiments of the invention are defined in the dependent claims.

The apparatus for vacuum coating substrates of various sizes according to the invention comprises several sequentially arranged lock and processing chambers as well as a conveying system for the sequential conveying of substrates in the lock chambers and for their continuous transport through the processing chambers. The substrates have a substrate width, and the lock and processing chambers' width corresponds to the substrate width. The lock chamber is characterized by a loading area A_{L} having a width w and a length l that indicates the size of the substrate that can be accommodated. According to the invention, this apparatus is characterized by the ratio R of width to length R=w/l being greater than a minimum ratio Rₘᵢₙ where
Rₘᵢₙ₌0.95−0.019 A_{L}.

Depending on the selected ratio R, the efficiency of the coating unit can be increased significantly.

In a preferred embodiment of the invention the lock and processing chambers are designed to have a width that allows for a coating performance of more than 3.21 m/min. Thus, the design of the chambers directly influences coating performance and, consequently, the efficiency of he coating unit.

In an advantageous embodiment, the invention is further designed such that each processing chamber, measured transverse (at right angle) to the direction of transport, is at least 3.30 m wide and, in another concrete embodiment, at least 3.70 m wide and that the ratio of width to length of each processing chamber is at least 0.7.

The apparatus according to the invention allows both flat glass panels measuring 100″×126″ and those measuring 100″×144″ to be coated, with at least two pieces of each type being placed in a processing chamber at the same time if they are placed adjacent to each other with their longest sides transverse (at right angle) to the direction of their movement.

Compared to conventional apparatuses of this type, the apparatus according to the invention thus doubles the efficiency of coating large-format substrates because now two substrates, instead of just one, can be accommodated in one processing chamber. Almost no coating material is wasted when larger substrates are being coated, since the substrates fill nearly the entire area of the processing chamber. Even when substrates of the smaller format are being coated in this apparatus, as much as ca. 88% of the processing chamber'area is utilized. As a result, the amount of wasted coating material and the required cleaning time and effort are much lower than is the case with conventional apparatuses of this type.

### BRIEF DESCRIPTION OF THE DRAWINGS

The invention will be described hereafter in more detail with reference to one particular embodiment. The accompanying drawing is a diagram showing the dimensions of the lock and processing chambers in comparison to prior art.

### DETAILED DESCRIPTION OF THE INVENTION

The loading areas are indicated on the left side of the diagram. Together with their width/length ratios, the customary substrate formats form pairs of variables that, according to the prior art, fall below a borderline. “Length” in this context measures the side of the loading area that is in line with the direction of transport. “Width” measures the side of the loading area that is at right angle to the length.

The borderline is described by the function Rₘᵢₙ=0.95−0.019 A_{L}. In the exemplary embodiment, the chamber width is selected such that the 100″×126″ and 100″×144″ formats can be introduced with their long sides transverse (at right angle) to the length of the coating unit. This means that a chamber width is selected that corresponds to that of the largest substrate width of these two formats, i.e., 3658 mm. For example, the chamber width here may be 3700 mm. Based on these dimensions, pairs of variables result for these two formats that are above the borderline, as is indicated in the diagram. This coating unit allows for a coating performance of 5.08 m/min, which is a significant increase in efficiency compared to what is possible with prior art.

1. An apparatus for vacuum coating of substrates of various sizes, comprising:
lock chambers at an entrance and at an exit and several processing chambers arranged one behind the other;
a conveying system for the sequential transport of substrates with a certain substrate width through the lock chambers and for their continuous transport through the processing chambers;
the lock and processing chambers comprising a chamber width corresponding to the substrate width; and
the lock chamber comprising a loading area A_{L} having a width b and a length l that indicates the size of the substrate that can be accommodated and wherein a ratio R of width to length R=w/l is greater than a minimum ratio Rₘᵢₙ where
Rₘᵢₙ=0.95−0.019 A_{L}.

2. The apparatus according to claim 1, wherein the lock and processing chambers having a chamber width that allows for a coating performance of more than 3.21 m/min.

3. The apparatus according to claim 1 wherein the width of each processing chamber, measured transversely to the direction of transport, is at least 3.30 m and that the ratio of width to length of each processing chamber is at least 0.7.

4. The apparatus according to claim 3, wherein each processing chamber is at least 3.70 m wide.

5. The apparatus according to claim 2 wherein the width of each processing chamber, measured transversely to the direction of transport, is at least 3.30 m and that the ratio of width to length of each processing chamber is at least 0.7.
